(19) United States
(12) Patent Application Publication
(10) Pub. No.: US 2010/0186667 A1
(43) Pub. Date: Jul. 29, 2010

(54) VERTICAL HEAT PROCESSING APPARATUS AND COMPONENT FOR SAME, FOR FORMING HIGH DIELECTRIC CONSTANT FILM

(75) Inventors: Katsutoshi ISHII, Nirasaki-shi (JP); Yoshihiro Ishida, Nirasaki-shi (JP); Katsushige Harada, Nirasaki-shi (JP); Haruhiko Furuya, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/684,321

(22) Filed: Jan. 8, 2010

(30) Foreign Application Priority Data
Jan. 26, 2009 (JP) 2009-014645

(51) Int. Cl. C23C 16/54

(52) U.S. Cl. 118/712; 118/725

(57) ABSTRACT

A vertical heat processing apparatus for forming a high dielectric constant film of a metal oxide by deposition includes a reaction container configured to accommodate a plurality of target substrates at intervals in a vertical direction; a support member configured to support the target substrates inside the reaction container; a heater configured to heat the target substrates inside the reaction container; an exhaust system configured to exhaust gas from inside the reaction container; and a gas supply system configured to supply a metal source gas and an oxidizing gas into the reaction container, wherein the gas supply system includes a gas nozzle disposed inside the reaction container, and the gas nozzle is made of a metal consisting mainly of titanium.

### BACKGROUND OF THE INVENTION

1. Field of the Invention

The present invention relates to a vertical heat processing apparatus for forming a high dielectric constant film by deposition on target substrates, such as semiconductor wafers, and a component for the apparatus, and particularly relates to a semiconductor processing technique. The term “semiconductor process” used herein includes various kinds of processes which are performed to manufacture a semiconductor device or a structure having wiring layers, electrodes, and the like to be connected to a semiconductor device, on a target substrate, such as a semiconductor wafer or a glass substrate used for an FPD (Flat Panel Display), e.g., an LCD (Liquid Crystal Display), by forming semiconductor layers, insulating layers, and conductive layers in predetermined patterns on the target substrate.

2. Description of the Related Art

As a semiconductor device manufacturing apparatus for performing a heat process on the surface of a target substrate, such as a semiconductor wafer (which may be simply referred to as a wafer), there is a vertical heat processing apparatus of the hot wall type, which is a so-called batch furnace. A vertical heat processing apparatus includes a vertical reaction tube or reaction container made of, e.g., quartz with a heater disposed around it. A number of wafers are held on a holder or wafer boat as in shelves and are loaded into the reaction tube. A process gas is supplied into the reaction tube while the reaction tube is heated by the heater, so that a heat process is performed on the wafers all together.

The heat processes performed in vertical heat processing apparatuses include film formation processes using CVD (Chemical Vapor Deposition), such as low pressure CVD, ALD (Atomic Layer Deposition), and MLD (Molecular Layer Deposition). A method of the ALD or MLD type is arranged to alternately supply a source gas and a reaction gas to repeatedly form layers each having an atomic or molecular level thickness, one by one, or several by several, thereby stacking the layers to form a film having a predetermined thickness.

The reaction tube of a vertical heat processing apparatus is provided with various structural parts for heat processes disposed therein (a structural part of this kind may be simply referred to as a component). Examples of such components are a gas injector (or gas nozzle) for supplying a process gas, such as a source gas or reaction gas, a wafer boat for holding wafers, and a protection tube that envelops a temperature detecting member, such as a thermocouple, for measuring the temperature inside the reaction tube. Conventionally, these components are made of quartz, so that they are prevented from being corroded by a precursor or source gas and a reaction gas, such as an oxidizing gas, and they do not cause contamination with impurities in a film to be formed.

However, as described later, the present inventors have found that conventional vertical heat processing apparatuses of this kind have room for improvement in terms of some characteristics of the apparatus concerning the service life and particle generation.

### BRIEF SUMMARY OF THE INVENTION

An object of the present invention is to provide a vertical heat processing apparatus for forming a high dielectric constant film and a component for the apparatus, which can improve characteristics of the apparatus concerning the service life and particle generation.

According to a first aspect of the present invention, there is provided a vertical heat processing apparatus for forming a high dielectric constant film of a metal oxide by deposition, the apparatus comprising: a reaction container configured to accommodate a plurality of target substrates at intervals in a vertical direction; a support member configured to support the target substrates inside the reaction container; a heater configured to heat the target substrates inside the reaction container; an exhaust system configured to exhaust gas from inside the reaction container; and a gas supply system configured to supply a metal source gas and an oxidizing gas into the reaction container, wherein the gas supply system includes a gas nozzle disposed inside the reaction container, and the gas nozzle is made of a metal consisting mainly of titanium.

According to a second aspect of the present invention, there is provided a component to be used in a vertical heat processing apparatus for forming a high dielectric constant film of a metal oxide by deposition on a plurality of target substrates by heating a reaction container that accommodates the target substrates at intervals in a vertical direction and supplying a metal source gas and an oxidizing gas into the reaction container, wherein the component is configured to be disposed inside the reaction container and is made of a metal consisting mainly of titanium.

According to a third aspect of the present invention, there is provided a heat-insulating cylinder to be used in a vertical heat processing apparatus for forming a high dielectric constant film of a metal oxide by deposition on a plurality of target substrates held on a holder at intervals in a vertical direction and accommodated in a reaction container, by heating the reaction container and supplying a metal source gas and an oxidizing gas into the reaction container, wherein the heat-insulating cylinder is placed between the holder and a lid that closes a load port formed at a lower end of the reaction container, the heat-insulating cylinder comprising: a pedestal configured to mount the holder thereon, and including a plurality of pole braces, a top plate fixing upper ends of the pole braces, and a bottom plate fixing lower ends of the pole braces; and a plurality of fins attached to the pole braces below the top plate and serving as baffle plates for preventing heat transmission in a vertical direction inside the reaction container, wherein the pole braces and the top plate are made of a metal consisting mainly of titanium, and the fins are made of opaque quartz.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below,

serve to explain the principles of the invention. FIG. 1 is a sectional side view showing a vertical heat processing apparatus according to an embodiment of the present invention;

FIG. 2 is a view for explaining the gas supply system and exhaust system of the vertical heat processing apparatus shown in FIG. 1;

FIG. 3A is an enlarged sectional side view showing the connection state of a gas injector disposed in the vertical heat processing apparatus shown in FIG. 1;

FIG. 3B is an enlarged sectional side view showing the relationship of a protection tube enveloping temperature sensors relative to the outer and inner tubes of a reaction tube in the vertical heat processing apparatus shown in FIG. 1;

FIG. 4 is an illustration showing an enlarged image of a picture of a portion where film peeling has been caused in a high dielectric constant film deposited on a quartz member;

FIG. 5 is an illustration showing an enlarged image of a picture of a portion where a quartz member has been cracked due to film peeling of a high dielectric constant film deposited on the quartz member; and

FIG. 6 is a diagram showing the coefficient of linear thermal expansion CLE of various materials in association with an embodiment of the present invention.

### DETAILED DESCRIPTION OF THE INVENTION

In the process of developing the present invention, the inventors studied problems with regard to conventional vertical heat processing apparatuses. As a result, the inventors have arrived at the findings given below.

Specifically, owing to the demands of increased integration and miniaturization of semiconductor devices, insulating films used for semiconductor devices, such as a MOS-FET insulating film, are required to decrease leakage current flowing therethrough. In light of this, studies have been made to use a film (high dielectric constant film) consisting of a metal oxide, such as aluminum oxide, zirconium oxide, or hafnium oxide, which has a higher dielectric constant than silicon oxide, in place of a silicon oxide film conventionally used.

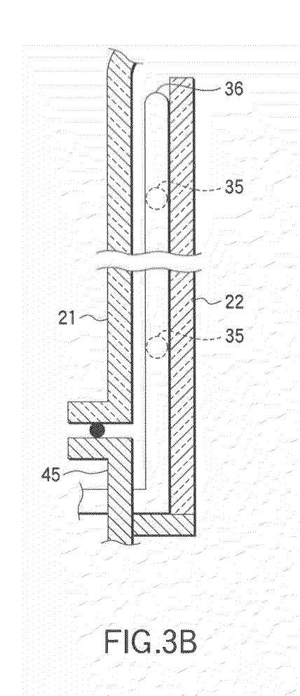

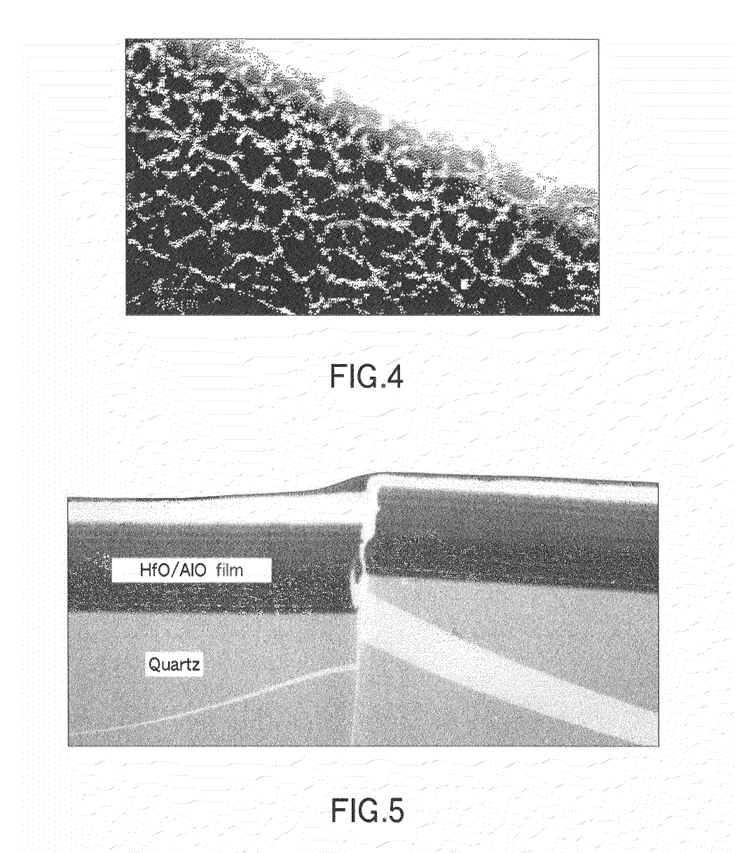

Incidentally, where film formation is performed in a vertical heat processing apparatus, components disposed inside the reaction tube thereof come into contact with a process gas while they are heated, and so films are deposited on these components as well as wafers. A high dielectric constant film of the kind described above has high adhesiveness to quartz and has a coefficient of linear thermal expansion 15 to 20 times larger than that of quartz, for example, unlike the silicon oxide film having the same composition as quartz. Where such a high dielectric constant film is deposited on a quartz component and increases its thickness, a large stress is applied from the high dielectric constant film to the quartz component, e.g., when the wafer boat is loaded, due to a rapid temperature change inside the reaction tube and on the wafer boat. Particularly, as shown in FIG. 4, when film peeling is caused in the high dielectric constant film, an excessive stress is applied to the quartz component. Consequently, as shown in FIG. 5, the quartz component is cracked and drastically deteriorates its mechanical strength, thereby ending up with early fracture.

Jpn. Pat. Appln. KOKAI Publication No. 2008-28307 discloses a vertical heat processing apparatus in which components, such as gas injectors and a wafer boat, are made of silicon carbide or silicon. However, the coefficient of linear thermal expansion of these components are almost half of that of the high dielectric constant film described above, and thus the stress applied to the components from the high dielectric constant film deposited thereon cannot be sufficiently decreased.

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

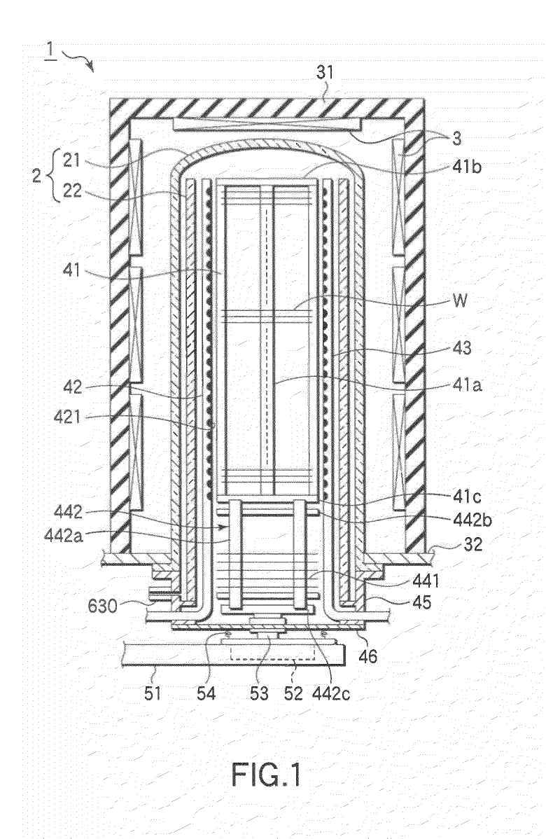

FIG. 1 is a sectional side view showing a vertical heat processing apparatus according to an embodiment of the present invention. FIG. 2 is a view for explaining the gas supply system and exhaust system of the vertical heat processing apparatus shown in FIG. 1. This film formation apparatus is designed as a vertical processing apparatus of the batch type to use an ALD or MLD method to form a high dielectric constant film consisting essentially of a metal oxide by deposition on a plurality of semiconductor wafers W.

As shown in FIG. 1, the vertical heat processing apparatus 1 includes a reaction container or reaction tube 2 for forming a film on wafers W. The reaction tube 2 is surrounded by a heat insulation cover 31 and a heater 3, which are used for heating the atmosphere inside the reaction tube 2 and the wafers W. The reaction tube 2 has a double-tube structure formed of an outer tube 21 and an inner tube 22 disposed therein, wherein the upper end of the outer tube 21 is closed while the upper and lower ends of the inner tube 22 are opened. The outer tube 21 and inner tube 22 are made of, e.g., transparent quartz or silicon carbide so that radiant energy from the heater 3 is efficiently transmitted.

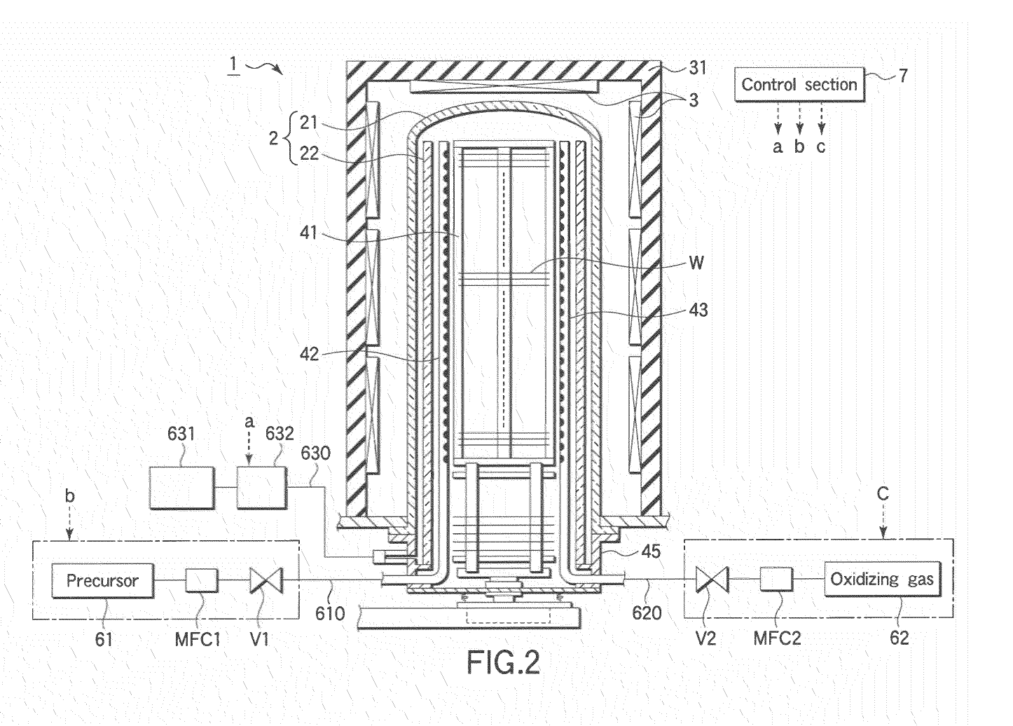

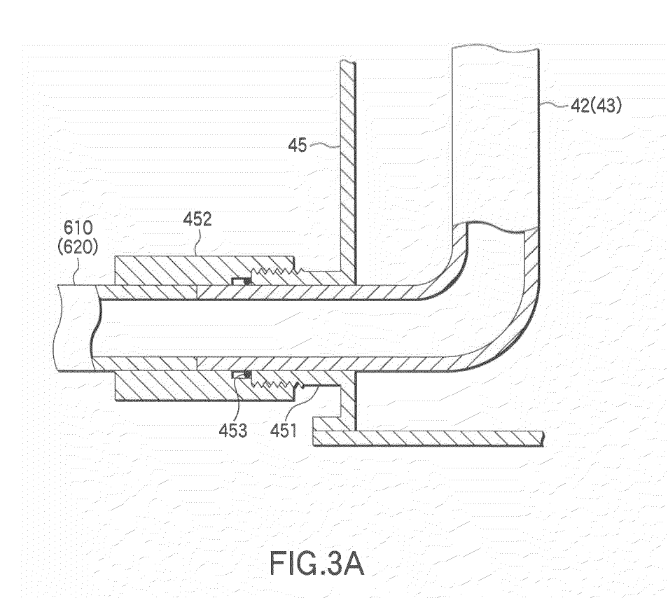

The heater 3 is supplied with an electric power from a power supply (not shown) under the control of a control section 7 described later, so that the temperature inside the reaction tube 2 is controlled. The heater 3 is formed of a plurality of heater portions disposed on the inner wall of the heat insulation cover 31 and separated in the vertical direction to define a plurality of heating zones. As shown in FIG. 3B, a plurality of temperature sensors 35 are disposed separately in the vertical direction between the outer tube 21 and inner tube 22 to measure the temperature of the respective zones. The temperature sensors 35 are formed of thermocouples and are enveloped by a common protection tube 36 extending in the vertical direction along the inner tube 22 (the wiring of the temperature sensors 35 is not shown). The protection tube 36 is lead out of the reaction tube 2 by use the same structure as that of the gas injectors 42 and 43 described later. The heater portions of the heater 3 are respectively controlled for the set temperature with reference to detection values of the temperature sensors 35. The temperature sensors 35 and protection tube 36 may be disposed inside the inner tube 22.

The lower ends of the outer tube 21 and inner tube 22 are supported by a cylindrical manifold 45. The heat insulation cover 31 and manifold 45 are fixed on a base plate 32. The lower end opening (load port) of the manifold 45 is selectively closed by a lid 46. The lid 46 is attached to a boat elevator 51 and moved thereby to open and close the opening of the manifold 45 by the lid 46. The boat elevator 51 is provided with a spring 54 for absorbing the impact applied by movement in the vertical direction.

A rotary shaft 53 extends through the center of the lid 46 and is connected at the upper end to a heat-insulating cylinder 44 and at the lower end to a rotating mechanism 52 disposed on the boat elevator 51. The heat-insulating cylinder 44 serves to support a wafer boat 41 and set it at a predetermined area inside the reaction tube 2, and serves to prevent heat discharge from inside the reaction tube 2 through the load port. The heat-insulating cylinder 44 comprises a pedestal 442 on which the wafer boat 41 is mounted and a plurality of horizontal fins 441 attached to the pedestal 442 and each formed of a circular solid plate. The fins 441 are arranged as baffle plates for preventing heat transmission in the vertical direction inside the reaction tube 2, and each made of a low heat-transmission material, such as opaque quartz. The frame of the pedestal 442 is formed of, e.g., four pole braces 442a and a top plate 442b and a bottom plate 442c that fix the upper and lower ends of the pole braces 442a. The bottom plate 442c of the pedestal 442 is connected to the rotary shaft 53 described above. The fins 441 are fixed to the pole braces 442a at intervals in the vertical direction.

A wafer holder or wafer boat 41 is placed on the top plate of the pedestal 442 of the heat-insulating cylinder 44. The wafer boat 41 includes, e.g., four pole braces 41a having a number of grooves (slots) formed thereon to hold a plurality of, e.g., 125, wafers W at intervals in the vertical direction (as in shelves). The upper and lower ends of the pole braces 41a are connected to the top plate 41b and bottom plate 41c of the wafer boat 41, respectively. When the rotary shaft 53 is rotated, the wafer boat 41 is rotated horizontally along with wafers W held thereon inside the reaction tube 2.

An exhaust line 630 is connected to the manifold 45. As shown in FIG. 2, the exhaust line 630 is connected to a vacuum pump 631 through a pressure adjusting portion 632. The vacuum pump 631 serves to maintain a vacuum atmosphere inside the reaction tube 2 by exhausting gas from inside the reaction tube 2 through a cylindrical space between the outer tube 21 and inner tube 22. The pressure adjusting portion 632 is formed of, e.g., a pressure regulation valve, so that the pressure inside the reaction tube 2 is controlled by adjusting the opening degree of the regulation valve.

As shown in FIG. 2, a precursor supply line 610 is connected to the manifold 45 to supply a gaseous precursor as the metal source of a high dielectric constant film. Further, an oxidizing gas supply line 620 is connected to the manifold 45 to supply an oxidizing gas for reacting with the precursor. The precursor supply line 610 is provided with a precursor supply section 61, a mass flow controller MFC1 for adjusting the flow rate and supply pressure, and a valve V1 from the upstream side. The precursor supply section 61 comprises a precursor reservoir and a vaporizer for the same. The precursor supply line 610 is connected to a precursor injector 42 through the body of the manifold 45.

The precursor supplied from the precursor supply section 61 is exemplified by the following materials. Specifically, where a high dielectric constant film comprising aluminum oxide is formed, TMA (trimethyl aluminum) may be used. Where a high dielectric constant film comprising zirconium oxide is formed, TEMAZ (tetrakisethylmethylamino zirconium) may be used. Where a high dielectric constant film comprising hafnium oxide is formed, TEMHF (tetrakisethylmethylamino hafnium) may be used. Where a high dielectric constant film comprising titanium oxide is formed, TiCl₄ may be used.

The oxidizing gas supply line 620 is provided with an oxidizing gas supply section 62, a mass flow controller MFC2, and a valve V2 from the upstream side. The oxidizing gas supply section 62 is formed of an oxygen cylinder or ozone generator for supplying oxygen or ozone as the oxidizing gas. The oxidizing gas supply line 620 is connected to an oxidizing gas injector 43 through the body of the manifold 45.

The precursor injector 42 and oxidizing gas injector 43 are disposed inside the reaction tube 2, as shown in FIG. 1. These injectors 42 and 43 have essentially the same structure, and so the precursor injector 42 will be explained as an example. The injector 42 is formed of a so-called gas distribution nozzle formed of a slender tube with an closed distal end and a number of gas delivery holes 421 formed therein at intervals over all the wafers W supported on the wafer boat 41. The injector 42 is disposed to extend essentially in the vertical direction in a space between the wafer boat 41 and inner tube 22.

The gas delivery holes 421 of the injector 42 are opened in a row in the vertical direction to face the peripheral side of the wafer boat 41 at height positions corresponding to the wafers W supported on the wafer boat 41. The gas from the gas delivery holes 421 flows toward the center of the reaction tube 2 and is supplied to the wafers W in a laminar flow state. The expression “height positions corresponding to the wafers W” is not limited to a case where the height positions of the gas delivery holes 421 are exactly the same as the height positions of the wafers W supported on the wafer boat 41. For example, the height positions may be shifted in the vertical direction by several millimeters, or each of the gas delivery holes 421 may cover several wafers W.

As shown in FIG. 3A, the lower end side of the injector 42 extends through a connection port 451 formed of a branch-like tube connected to the body of the manifold 45. The injector 42 is bent essentially at a right angle at the height position of the connection port 451 and is inserted into the connection port 451. The end side of the injector 42 inserted into the connection port 451 extends out of the connection port 451 and is connected to the pipe of the precursor supply line 610 through a joint pipe 452.

Specifically, the joint pipe 452 has a screw portion formed on the inner surface. Further, the connection port 451 has the corresponding screw portion formed on the outer surface. The joint pipe 452, in which the end of the pipe of the precursor supply line 610 is inserted, is screwed onto the connection port 451, from which the end of the injector 42 is projected. Consequently, the ends of the injector 42 and the precursor supply line 610 are set to abut with each other and are connected to each other. An O-ring 453 is disposed to make sure that the portion between the end of the injector 42 and the connection port 451 is airtight.

On the other hand, the oxidizing gas injector 43 has essentially the same structure as the precursor injector 42 described above. The lower end side of the oxidizing gas injector 43 is inserted into another connection port 451 disposed on the manifold 45, as shown in FIG. 3A, and is connected to the pipe of the oxidizing gas supply line 620 by an joint pipe 452.

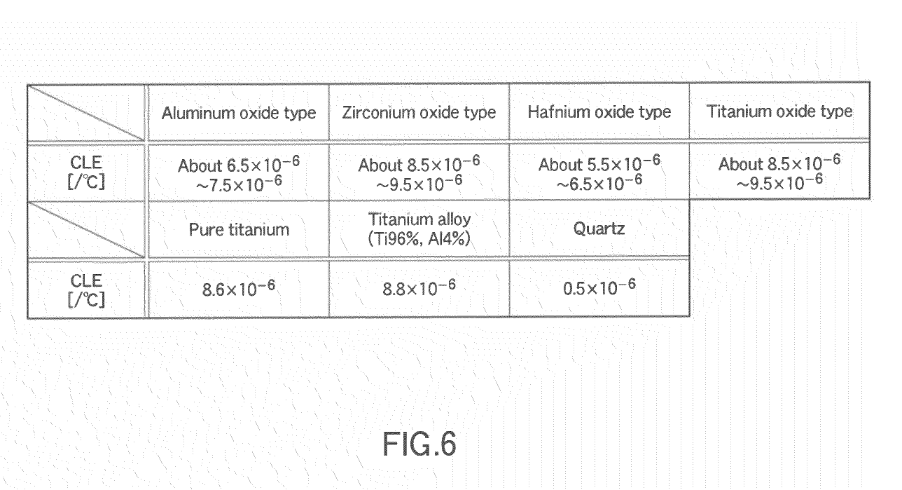

The injectors 42 and 43 are made of a metal (pure metal or alloy) consisting mainly of titanium (it means more than 50 wt % (% by weight)). This is conceived to make less serious the influence of a stress due to expansion and contraction of a high dielectric constant film, which has been deposited on the surface of the injectors 42 and 43 by film formation performed inside the reaction tube 2. FIG. 6 is a diagram showing the coefficient of linear thermal expansion CLE of various materials in association with an embodiment of the present invention. Specifically, FIG. 6 shows data of high dielectric constant materials of the aluminum oxide type, zirconium oxide type, hafnium oxide type, and titanium oxide type, and data of pure titanium, a titanium alloy (96 wt % titanium and 4 wt % aluminum), and quartz (conventional injector material). It should be noted that, if the coefficient of linear thermal expansion CLE of a certain material has temperature dependency, a value shown here is the average within a range of temperature to which the injectors 42 and 43 are exposed when the high dielectric constant films are formed.

As shown in FIG. 6, the coefficient of linear thermal expansion CLE of quartz is one twentieth to one tenth of those of the high dielectric constant materials, and thus quartz hardly causes expansion and contraction with changes in temperature. Accordingly, when a high dielectric constant film deposited on quartz causes expansion and contraction with changes in temperature, the quartz may be cracked by a stress applied from the film.

On the other hand, the coefficient of linear thermal expansion of pure titanium or the titanium alloy differs from those of the high dielectric constant materials by about −10% to +25% at most. In other words, FIG. 6 shows that pure titanium or the titanium alloy has a characteristic such that it causes expansion and contraction almost the same as the high dielectric constant materials do with changes in ambient temperature. Accordingly, where the injectors 42 and 43 are made of pure titanium or the titanium alloy and a high dielectric constant film is deposited on the injectors 42 and 43, the high dielectric constant film and injectors 42 and 43 cause expansion and contraction to almost the same degree with changes in ambient temperature.

As described above, the injectors 42 and 43 consisting mainly of titanium can hardly receive a stress from a high dielectric constant film deposited thereon, or can receive a far smaller stress if any, as compared with quartz injectors. Further, since the injectors 42 and 43 can be hardly cracked, they are unlikely to deteriorate their mechanical strength or end up with early fracture.

In addition to this advantage, titanium and titanium alloy have very high affinity with oxygen, and an oxide film serving as a passivation film is formed on their surface when they are heat-processed within an oxidizing atmosphere. This passivation film covering the surface enhances the corrosion resistance and oxidation resistance of the injectors 42 and 43, and can prevent contamination to high dielectric constant films. For example, the passivation film may be formed by supplying an oxidizing gas, such as oxygen or ozone, from the oxidizing gas supply section 62, while heating the reaction tube 2 by the heater 3 at a temperature of about 400 to 700° C. for about 30 to 120 minutes, before the vertical heat processing apparatus 1 is used for film formation for the first time. According to this method, the oxidizing gas delivered from the oxidizing gas injector 43 cannot be sufficiently supplied into the precursor injector 42. In light of this, for example, when the precursor injector 42 is manufactured, it may be heat-processed within an oxidizing atmosphere to form a passivation film thereon before it is installed inside the reaction tube 2. Further, for example, the passivation film may be formed in advance by an anodic oxidation process or another method. It should be noted that, in the case of the precursor injector 42, a high dielectric constant material is deposited not only on the outer surface but also on the inner surface due to thermal decomposition of the precursor.

FIG. 6 shows a titanium alloy containing aluminum at a concentration of 4 wt % as an example. The present inventors have confirmed that titanium alloys containing aluminum have high stability relative to corrosion by the precursor. In this respect, a titanium alloy adoptable as the material of the injectors 42 and 43 is not limited to the example shown in FIG. 6, but may be a metal consisting mainly of titanium (pure metal or an alloy). The expression “a metal consisting mainly of titanium” means a metal containing titanium to a degree with which the coefficient of linear thermal expansion of the metal approximates the coefficient of linear thermal expansion of a high dielectric constant film to be formed in the vertical heat processing apparatus 1. Consequently, a component made of this metal and the high dielectric constant film formed thereon cause expansion and contraction to almost the same degree, so that the stress applied from the high dielectric constant film to the component becomes very small. This effect should be sufficiently obtained where the titanium content in the metal is 70 wt % or more (including the case of pure titanium).

The vertical heat processing apparatus 1 includes a control section 7 that exercises temperature control by the heater 3, pressure adjustment by the pressure adjusting portion 632, flow rate adjustment by the mass flow controllers MFC1 and MFC2, vertical movement of the boat elevator 51, and rotational movement of the rotating mechanism 52. The control section 7 comprises a computer including, e.g., a CPU and a storage section that stores programs. The programs includes a group of steps (commands) for controlling the vertical heat processing apparatus 1 to conduct various operations necessary for performing film formation on the wafers W. For example, this program is stored in a storage medium, such as a hard disk, compact disk, magneto-optical disk, or memory card, and is installed therefrom into the computer.

Next, an explanation will be given of a film formation process performed in the vertical heat processing apparatus 1 according to this embodiment. At first, a predetermined number of wafers W are placed as in shelves on the wafer boat 41 outside the reaction tube 2. Then, the boat elevator 51 is moved up to load the wafers W into the reaction tube 2. With this operation, the wafer boat 41 is set at a predetermined position and the lower end opening of the manifold 45 is closed by the lid 46. Then, the main valve (not shown) is opened to exhaust gas from inside the reaction tube 2 through the exhaust line 630 by the vacuum pump 631 at full throttle. The temperature inside the reaction tube 2 is kept at a predetermined temperature of, e.g., about 200 to 400° C. from before the wafer boat 41 is loaded.

After the temperature and pressure inside the reaction tube 2 obtained by temperature increase and exhaust are stabilized, the precursor gas (source gas) is supplied from the injector 42 at a predetermined flow rate for, e.g., several seconds to several tens of seconds. At this time, a molecular layer of the precursor is adsorbed on the wafers W supported on the wafer boat 41. Then, the gas supplied into the reaction tube 2 is switched, so that the oxidizing gas is supplied from the injector 43 at a predetermined flow rate for, e.g., several seconds to several tens of seconds. At this time, the oxidizing gas reacts with the precursor adsorbed on the wafers W, and a molecular layer of a high dielectric constant material is thereby formed on the wafers W.

One cycle comprises a step of supplying the source gas (precursor) and a step of supplying the oxidizing gas, and is repeated several tens of times and several hundreds of times. Consequently, molecular layers of the high dielectric constant material are laminated on the wafers W, and a high dielectric constant film having a predetermined thickness is thereby formed. During this cycle, the interior of the reaction tube 2 is kept at a vacuum atmosphere of, e.g., several hundreds of Pa (several Torr) by the pressure adjusting portion 632, and the wafer boat 41 is rotated by the rotating mechanism 52.

After a high dielectric constant film having a predetermined thickness is formed on the wafers W by the steps described above, the cycle of supplying the precursor and oxidizing gas into the reaction tube 2 is finished. Then, the vacuum pump 631 stops exhausting gas, and a gas, such as air or nitrogen, is supplied into the reaction tube 2 to return the pressure inside the reaction tube 2 to atmospheric pressure. Then, the temperature inside the reaction tube 2 is lowered to, e.g., about 200 to 400° C. Then, the wafer boat 41 is moved down by the boat elevator 51, so that the wafers W are unloaded from the reaction tube 2.

The heat process from the loading to unloading of the wafers W described above is repeatedly performed in the vertical heat processing apparatus 1. As the process is repeated, the high dielectric constant material is gradually deposited and forms a film on the two injectors 42 and 43 inside the reaction tube 2. The temperature of the atmosphere surrounding the injectors 42 and 43 varies, depending on the period of time, for example, between the heat process and the unloading of the wafers W. Due to these temperature changes, the injectors 42 and 43 and the high dielectric constant film deposited thereon repeat expansion and contraction. Further, for example, between the running and suspension of the vertical heat processing apparatus 1, the temperature also varies between room temperature and a temperature of several hundreds of ° C.

The injectors 42 and 43 are made of titanium or a titanium alloy, which has a coefficient of linear thermal expansion close to that of the high dielectric constant material, and so the injectors 42 and 43 and the high dielectric constant film deposited thereon cause expansion and contraction to almost the same degree. Consequently, the stress applied from the high dielectric constant film to the injectors 42 and 43 becomes smaller, as compared to a case where they are made of quartz.

The embodiment described above provides the following effects. Specifically, the vertical heat processing apparatus according to this embodiment comprises the reaction tube 2 designed to form a high dielectric constant film of, e.g., aluminum oxide, zirconium oxide, hafnium oxide, or the like. The injectors 42 and 43 disposed inside the reaction tube 2 for supplying the precursor and oxidizing gas are made of a metal consisting mainly of titanium, which has a coefficient of linear thermal expansion close to that of the high dielectric constant material. In this case, the injectors 42 and 43 and the high dielectric constant film deposited thereon cause expansion and contraction to almost the same degree with changes in temperature, and so the stress applied from the high dielectric constant film to the injectors 42 and 43 becomes far smaller. Consequently, the injectors 42 are unlikely to deteriorate their mechanical strength or end up with early fracture.

It should be noted that a component other than the injectors 42 and 43, which is disposed inside the reaction tube 2 and exposed to the heat process atmosphere, may be made of titanium or titanium alloy to make less serious the influence of the stress applied from a high dielectric constant film deposited thereon.

In a first modification of the embodiment, the frame of the wafer boat 41 for holding the wafers W and the frame of the pedestal 442 of the heat-insulating cylinder 44 are also made of a metal consisting mainly of titanium described above. Specifically, in this first modification, the pole braces 41a, top plate 41b, and bottom plate 41c forming the frame of the wafer boat 41, and the pole braces 442a, top plate 442b, and bottom plate 442c forming the frame of the pedestal 442 are made of a metal consisting mainly of titanium described above. However, the horizontal fins 441 attached to the pole braces 442a of the pedestal 442 are made of a low heat-transmission material, such as opaque quartz, because they are baffle plates for preventing heat transmission.

In a second modification of the embodiment, the protection tube 36 (see FIG. 3B) disposed inside the reaction tube 2 and enveloping the temperature sensors 35 for measuring the temperature of the respective heating zones is also made of a metal consisting mainly of titanium described above.

Even where a component is disposed at a height position inside the manifold 45 shown in FIG. 1, the component receives heat from the heater 3 and a high dielectric constant film may be deposited thereon. In such as case, the component is considered as being disposed inside the heat process atmosphere of the reaction container.

The embodiment described above is exemplified by a process for forming by an ALD or MLD method a high dielectric constant film consisting of a single high dielectric constant material. In this respect, the present invention may be applied to a process for forming a high dielectric constant film by alternately laminating molecular layers of a plurality of high dielectric constant materials selected from the group consisting of aluminum oxide, zirconium oxide, and hafnium oxide, for example. Further, the present invention may be applied to a process for forming a high dielectric constant film by adding a high dielectric constant material of another type or silicon oxide. Furthermore, the present invention may be applied to an ordinary CVD process for forming a high dielectric constant film by continuously supplying a precursor and an oxidizing gas, or by continuously supplying a precursor and thermal decomposing it.

Where a high dielectric constant film of aluminum oxide is formed, an alumina material, such as sapphire or SAPPHAL™, may be used as a component material in place of titanium or titanium alloy. Since the aluminum oxide and alumina material are close in the coefficient of linear thermal expansion, the stress applied to the component from the high dielectric constant film deposited thereon is decreased. Accordingly, in general, a material is selected to have a coefficient of linear thermal expansion close to that of a high dielectric constant film to be formed on wafers W by a heat process, and a component to be disposed inside the heat process atmosphere of a reaction container, such as the reaction tube 2, is made of the material. Consequently, the stress applied to the component from the high dielectric constant film deposited thereon is decreased.

A target substrate is not limited to a semiconductor wafer, and it may be another substrate, such as an LCD substrate or glass substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A vertical heat processing apparatus for forming a high dielectric constant film of a metal oxide by deposition, the apparatus comprising:
a reaction container configured to accommodate a plurality of target substrates at intervals in a vertical direction;
a support member configured to support the target substrates inside the reaction container;
a heater configured to heat the target substrates inside the reaction container;
an exhaust system configured to exhaust gas from inside the reaction container; and
a gas supply system configured to supply a metal source gas and an oxidizing gas into the reaction container,
wherein the gas supply system includes a gas nozzle disposed inside the reaction container, and the gas nozzle is made of a metal consisting mainly of titanium.

2. The apparatus according to claim 1, wherein the support member includes a pole brace made of a metal consisting mainly of titanium.

3. The apparatus according to claim 1, wherein the apparatus further includes a protection tube disposed inside the reaction container and enveloping a temperature detecting member, and the protection tube is made of a metal consisting mainly of titanium.

4. The apparatus according to claim 1, wherein the heater is disposed around the reaction container, and the reaction container is made of quartz or silicon carbide to transmit radiant energy from the heater.

5. The apparatus according to claim 1, wherein the metal consisting mainly of titanium has a titanium content of 70 wt % or more.

6. The apparatus according to claim 5, wherein the metal consisting mainly of titanium has a coefficient of linear thermal expansion, which is −10% to +25% of that of the metal oxide of the high dielectric constant film.

7. The apparatus according to claim 6, wherein the metal oxide of the high dielectric constant film is selected from the group consisting of aluminum oxide, zirconium oxide, hafnium oxide, and titanium oxide.

8. The apparatus according to claim 6, wherein the metal consisting mainly of titanium is a titanium alloy containing aluminum.

9. The apparatus according to claim 1, wherein the gas nozzle has a surface covered with a passivation film formed by oxidizing the surface,

10. The apparatus according to claim 1, wherein the gas nozzle is a gas distribution nozzle with a plurality of gas delivery holes formed therein at intervals over all the target substrates supported on the support member.

11. A component to be used in a vertical heat processing apparatus for forming a high dielectric constant film of a metal oxide by deposition on a plurality of target substrates by heating a reaction container that accommodates the target substrates at intervals in a vertical direction and supplying a metal source gas and an oxidizing gas into the reaction container, wherein the component is configured to be disposed inside the reaction container and is made of a metal consisting mainly of titanium.

12. The component according to claim 11, wherein the metal consisting mainly of titanium has a titanium content of 70 wt % or more.

13. The component according to claim 12, wherein the metal consisting mainly of titanium has a coefficient of linear thermal expansion, which is −10% to +25% of that of the metal oxide of the high dielectric constant film.

14. The component according to claim 13, wherein the metal oxide of the high dielectric constant film is selected from the group consisting of aluminum oxide, zirconium oxide, hafnium oxide, and titanium oxide.

15. The component according to claim 13, wherein the metal consisting mainly of titanium is a titanium alloy containing aluminum.

16. The component according to claim 11, wherein the heater is disposed around the reaction container, and the reaction container is made of quartz or silicon carbide to transmit radiant energy from the heater.

17. The component according to claim 11, wherein the component has a surface covered with a passivation film formed by oxidizing the surface,

18. The component according to claim 11, wherein the component is selected from the group consisting of a gas nozzle, a pole brace of a support member configured to support the target substrates, and a protection tube enveloping a temperature detecting member.

19. The component according to claim 11, wherein the component is a gas distribution nozzle with a plurality of gas delivery holes formed therein at intervals over all the target substrates supported on a support member.

20. A heat-insulating cylinder to be used in a vertical heat processing apparatus for forming a high dielectric constant film of a metal oxide by deposition on a plurality of target substrates held on a holder at intervals in a vertical direction and accommodated in a reaction container, by heating the reaction container and supplying a metal source gas and an oxidizing gas into the reaction container, wherein the heat-insulating cylinder is placed between the holder and a lid that closes a load port formed at a lower end of the reaction container, the heat-insulating cylinder comprising:
a pedestal configured to mount the holder thereon, and including a plurality of pole braces, a top plate fixing upper ends of the pole braces, and a bottom plate fixing lower ends of the pole braces; and
a plurality of fins attached to the pole braces below the top plate and serving as baffle plates for preventing heat transmission in a vertical direction inside the reaction container,
wherein the pole braces and the top plate are made of a metal consisting mainly of titanium, and the fins are made of opaque quartz.
